(19) United States
(12) Patent Application Publication
(10) Pub. No.: US 2026/0055318 A1
(43) Pub. Date: Feb. 26, 2026

(54) QUANTUM DOT CORE, QUANTUM DOT INCLUDING THE SAME, AND ELECTRONIC APPARATUS INCLUDING THE QUANTUM DOT

(71) Applicant: Samsung Display Co., Ltd., Yongin-si (KR)

(72) Inventors: Youngsik Kim, Yongin-si (KR); Sungjae Kim, Yongin-si (KR); Hongrae Kim, Yongin-si (KR); Juo Nam, Yongin-si (KR); Seungwon Park, Yongin-si (KR); Bitna Yoon, Yongin-si (KR); Taekjoon Lee, Yongin-si (KR); Junehyuk Jung, Yongin-si (KR)

(73) Assignee: Samsung Display Co., Ltd., Yongin-si (KR)

(21) Appl. No.: 19/296,067

(22) Filed: Aug. 11, 2025

(30) Foreign Application Priority Data
Aug. 20, 2024 (KR) 10-2024-0111620

(51) Int. Cl. C09K 11/62; B82Y 20/00; B82Y 40/00; C01G 15/00; H10K 59/38

(52) U.S. Cl. CPC C09K 11/623; C01G 15/006; H10K 59/38; B82Y 20/00; B82Y 40/00; C01P 2004/64; C01P 2004/84; C01P 2006/60

(57) ABSTRACT

Provided are a quantum dot core, a quantum dot including the quantum dot core, and an electronic apparatus including the quantum dot. The quantum dot core includes a Group I-III-VI semiconductor compound. A ratio of an inorganic material in the quantum dot core is greater than or equal to about 80 wt %.

### CROSS-REFERENCE TO RELATED APPLICATION(S)

This application claims priority to and the benefits of Korean Patent Application No. 10-2024-0111620 under 35 USC § 119, filed Aug. 20, 2024, in the Korean Intellectual Property Office (KIPO), the entire contents of which are incorporated herein by reference.

### BACKGROUND

### 1. Technical Field

Embodiments relate to a quantum dot core, a quantum dot including the same, and an electronic apparatus including the quantum dot.

### 2. Description of the Related Art

Quantum dots are semiconductor nanoparticles with a several-nanometer size and have unique optoelectronic properties due to a quantum confinement effect. Due to a narrow emission line width and a band gap energy that is readily adjustable according to a particle size, quantum dots are being actively studied as an emission material for next-generation display technology, and in particular, there is an increasing demand for quantum dots with an eco-friendly composition that is harmless to the human body and the environment.

Displays using quantum dots require red, green, and blue quantum dots, and among the red, green, and blue quantum dots, research and development of red and green-emitting quantum dots with an eco-friendly composition has been carried out at a level close to commercialization. However, development is required.

### SUMMARY

Embodiments include a quantum dot core in which an amount of an organic material is significantly reduced on a surface of a quantum dot core, a quantum dot including the same, and an electronic apparatus including the quantum dot.

Additional aspects will be set forth in part in the description which follows and, in part, will be apparent from the description, or may be learned by practice of the embodiments of the disclosure.

According to an embodiment, a quantum dot core may include a Group I-III-VI semiconductor compound. A ratio of an inorganic material in the quantum dot core may be greater than or equal to about 80 wt %.

In an embodiment, the quantum dot core may include a plurality of quantum dot cores, a uniformity of the plurality of quantum dot cores may be less than or equal to about 19%, and

$$uniformity = ( standard deviation of the plurality of quantum dot cores / average diameter of the plurality of quantum dots ) \times 100.$$

In an embodiment, the quantum dot core may have a diameter in a range of about 1.0 nm to about 10 nm.

In an embodiment, a full width at half maximum of the quantum dot core may be less than or equal to about 49 nm.

In an embodiment, the Group I-III-VI semiconductor compound may include AgInS, AgInS₂, CuInS, CuInS₂, CuGaO₂, AgGaO₂, AgAlO₂, CuInGaS, CuInGaS₂, AgInGaS, AgInGaS₂, or a combination thereof.

In an embodiment, the Group I-III-VI semiconductor compound may include CuInGaS, CuInGaS₂, or a combination thereof, and a molar ratio of Cu to a total number of moles of Cu, In, Ga, and S in the quantum dot core may be in a range of about 0.01 to about 0.30.

In an embodiment, the Group I-III-VI semiconductor compound may include CuInGaS, CuInGaS₂, or a combination thereof, and a molar ratio of In to a total mole number of Cu, In, Ga, and S in the quantum dot core may be in a range of about 0.10 to about 0.60.

In an embodiment, the Group I-III-VI semiconductor compound may include CuInGaS, CuInGaS₂, or a combination thereof, and a molar ratio of Ga to a total number of moles of Cu, In, Ga, and S in the quantum dot core may be in a range of about 0.01 to about 0.30.

In an embodiment, the Group I-III-VI semiconductor compound may include CuInGaS, CuInGaS₂, or a combination thereof, and a molar ratio of S to a total number of moles of Cu, In, Ga, and S in the quantum dot core may be in a range of about 0.30 to about 0.70.

In an embodiment, the quantum dot core may have a blue light exposure stability value greater than or equal to about 65%, the blue light exposure stability may be obtained by exposing a solution, which has a concentration at which an optical density is 1 at 450 nm, to a light exposure environment of 200 nit at 450 nm for 2 hours and leaving the solution to obtain a photoluminescence quantum yield (PLQY) value, and

$$blue light exposure stability value = ( PLQY before exposure ) / ( PLQY after exposure ) \times 100.$$

According to an embodiment, a quantum dot may include the quantum dot core, and a shell. The shell may include ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, MgSe, CdS, CdSe, CdTe, ZnSeS, ZnTeS, HgS, HgSe, HgTe, InP, InGaP, or a combination thereof.

In an embodiment, a ratio of an inorganic material in the quantum dot may be greater than or equal to about 80 wt %.

In an embodiment, the shell may include ZnS, and a molar ratio of Cu to a total number of moles of the quantum dot may be in a range of about 0.20 to about 0.60.

In an embodiment, the shell may include ZnS, and a molar ratio of In to a total number of moles of the quantum dot may be in a range of about 0.10 to about 0.60.

In an embodiment, the shell may include ZnS, and a molar ratio of Ga to a total number of moles of the quantum dot may be in a range of about 0.05 to about 0.50.

According to an embodiment, an electronic apparatus may include a light-emitting device including a first electrode, a second electrode facing the first electrode, and an interlayer which is arranged between the first electrode and the second electrode and including an emission layer, a thin film transistor, and the quantum dot. The thin film transistor may include a source electrode and a drain electrode, and the first electrode of the light-emitting device may be electrically connected to at least one of the source electrode and the drain electrode of the thin film transistor.

In an embodiment, the electronic apparatus may further include a color conversion layer. The color conversion layer may include the quantum dot.

In an embodiment, the electronic apparatus may further include a capping layer.

In an embodiment, the capping layer may include a material having a refractive index (at 589 nm) greater than or equal to about 1.6.

In an embodiment, the electronic apparatus may include an authentication apparatus, a display, a light sources, a lighting, a personal computer, a mobile phone, a digital camera, an electronic organizer, an electronic dictionary, an electronic game machine, medical instrument, a fish finder, a measuring instrument, a meters, or a projector.

According to an embodiment, a method of preparing a quantum dot core including a Group I-III-VI semiconductor compound may include operation (1) of heating a metal halide, and operation (2) of adding a non-nucleophilic base, a reducing agent, or a combination thereof, and a sulfur precursor, to a resultant product of the operation (1) and causing a reaction at a temperature less than or equal to about 350° C. for less than or equal to about 30 minutes.

In an embodiment, the non-nucleophilic base may include lithiumhexamethyldisilazide (LiHMDS), sodiumhexamethyldisilazide (NaHMDS), lithium diisopropyl amide, sodium diisopropyl amide, lithium tert-butoxide, sodium tert-butoxide, or a combination thereof.

In an embodiment, the reducing agent may include lithium borohydride, lithium aluminum hydride, sodium borohydride, tris(2-carboxyethyl)phosphine hydrochloride, sodium hydride, or a combination thereof.

### BRIEF DESCRIPTION OF THE DRAWINGS

The above and other aspects, features, and advantages of embodiments will be more apparent from the following description taken in conjunction with the accompanying drawings, in which:

FIG. 1 shows graphs showing that a reaction rate of the disclosure is increased as compared to a related art in a method of preparing a quantum dot core according to an embodiment;

FIG. 2 shows scanning electron microscope images of a quantum dot core according to a related art and a quantum dot core according to an embodiment, each synthesized for a same period of time;

FIG. 3 shows graphs showing a full width at half maximum of a quantum dot core of Comparative Example and a full width at half maximum of a quantum dot core of Example;

FIG. 4 shows graphs showing a full width at half maximum of a quantum dot of Comparative Example and a full width at half maximum of a quantum dot of Example;

FIG. 5 shows graphs showing a ratio of an inorganic material of a quantum dot core of Comparative Example and a ratio of an inorganic material of a quantum dot core of Example;

FIG. 6 shows graphs showing a ratio of an inorganic material of a quantum dot of Comparative Example and a ratio of an inorganic material of a quantum dot of Example;

FIG. 7 is a graph showing photostabilities of a quantum dot core and a quantum dot of Comparative Examples and a quantum dot core and a quantum dot of Examples;

FIG. 8 is a schematic cross-sectional view illustrating a structure of a light-emitting device; and

FIG. 9 is a schematic cross-sectional view illustrating a structure of an electronic apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

By using a Group III-V compound and a Group I-III-VI compound which are environmentally friendly materials that do not contain heavy metal components, core-shell quantum dots may be prepared as non-Cd quantum dots. Typically, for InP, a ZnSe/ZnS shell may be used according to a band gap, and various synthesis methods may be used for a InP core-shell interface, a shell thickness, and defect removal.

In the case of AgInGaS quantum dots (AIGS QDs) with excellent full width at half maximum and excellent emission efficiency, it may be difficult to control surface defects and form a thick shell with shell materials (ZnS and ZnSe) used in most quantum dots (ZnS with a lattice spacing of 5.47 Å, ZnSe with a lattice spacing of 5.67 Å, AgInS₂ with a lattice spacing of 5.90 Å, and AgGaS₂ with a lattice spacing of 5.76 Å). Optical properties may be improved by using GaS shells, but there may be a problem in terms of optical stability due to difficulty in stacking thick shells. A quantum yield (QY) retention rate may be less than or equal to about 50% in case that light resistance is tested by irradiating blue light.

There is a need to secure quantum dots with high efficiency and stability by synthesizing a high-color reproducibility CuInGaS (CIGS) core and forming a robust shell. CuInS₂ has a lattice spacing of 5.52 Å, and CuGaS₂ has a lattice spacing of 5.33 Å, which makes it readily grow ZnSe and ZnS shells which are commonly used in quantum dots.

In a related art, quantum dot synthesis may have a slow reaction rate and thus may require a long time reaction, which causes the following problems.

A polymerization reaction of a solvent may form a polymer film on a surface of a quantum dot core. Thus, a shell in a subsequent process may not be grown readily and cause stability problems, and a ligand exchange reaction in a subsequent process may not occur readily. A slow reaction rate may decrease uniformity of core particles due to the inability to clearly separate a nucleation process and a growth process.

In a method of preparing a quantum dot core according to an embodiment, an additive (for example, a non-nucleophilic base, a reducing agent, or a combination thereof) may be added to accelerate a reaction rate to significantly reduce an amount of an organic material (for example, a polymer film) present on a core surface, thereby allowing a shelling process and a ligand exchange reaction to proceed readily and improving the uniformity of core particles.

A method of preparing a quantum dot core including a Group I-III-VI semiconductor compound according to an embodiment may include operation (1) of heating a metal halide, and operation (2) of adding a non-nucleophilic base, a reducing agent, or a combination thereof, and a sulfur precursor, to a resultant product of the operation (1), and causing a reaction at a temperature less than or equal to about 350° C. for less than or equal to about 30 minutes.

The metal halide may include a cation precursor used in a Group I-III-VI semiconductor compound and may be, for example, CuX, InX₃, GaX₃, or the like (X may be F, Cl, Br, or I).

For example, the operation (1) may be an operation of stirring the cation precursor in a solvent at a temperature in a range of about 100° C. to about 150° C. for about 0.5 hours to about 2 hours. For example, the solvent may be an organic solvent (or may also include heteroatoms). For example, the solvent may be oleylamine, octadecene, or a mixture thereof.

In the method of preparing a quantum dot core including a Group I-III-VI semiconductor compound according to an embodiment, in the operation (2), a non-nucleophilic base, a reducing agent, or a combination thereof may be added to cause a reaction so that a reaction rate may be accelerated so that an amount of an organic material (for example, a polymer film) present on a core surface may be significantly reduced, and the uniformity of core particles may be improved. This is apparently because the non-nucleophilic base, the reducing agent, or a combination thereof may make a metal halide, which is a precursor, and a sulfur precursor reactive.

According to an embodiment, in the operation (2), the non-nucleophilic base may include Lithium bis(trimethylsilyl)amide, sodium bis(trimethylsilyl)amide, lithium diisopropyl amide, sodium diisopropyl amide, lithium tert-butoxide, sodium tert-butoxide, or a combination thereof.

According to an embodiment, in the operation (2), the reducing agent may include lithium borohydride, lithium aluminum hydride, sodium borohydride, tris(2-carboxyethyl)phosphine hydrochloride, sodium hydride, or a combination thereof.

A quantum dot core prepared by the method of preparing a quantum dot core including a Group I-III-VI semiconductor compound according to an embodiment may be purified and subjected to a general shell growth process to be prepared into a quantum dot having a core/shell structure.

A quantum dot core according to an embodiment may include a Group I-III-VI semiconductor compound, and a ratio of an inorganic material in the quantum dot core may be greater than or equal to about 80 wt %.

When the quantum dot core according to an embodiment is prepared, a non-nucleophilic base, a reducing agent, or a combination thereof may be added to cause a reaction, thereby accelerating a reaction rate and significantly reducing an amount of an organic material (for example, a polymer film) present on a core surface. The organic material present on the core surface may be present, for example, in an amount less than or equal to about 20 wt %.

According to an embodiment, the uniformity of the quantum dot core may be less than or equal to about 19%.

$$uniformity = ( standard deviation / diameter ) \times 100$$

By adding a non-nucleophilic base, a reducing agent, or a combination thereof when the quantum dot core according to an embodiment is prepared, a metal halide and a sulfur precursor may become reactive, and a reaction rate may be accelerated to generate a large amount of nuclei. A monomer supplied to grow particles (for example, a metal atom, a metal ion, a composite of a metal atom and an organic/inorganic ligand, a composite of a metal ion and an organic/inorganic ligand, a non-metal atom, a composite of a non-metal atom and an organic/inorganic ligand, a non-metal ion, a composite of a non-metal ion and an organic/inorganic ligand, or the like) may be rapidly consumed so that the quantum dot core may become relatively more uniform.

According to an embodiment, the quantum dot core may have a diameter in a range of about 1.0 nm to about 10 nm. For example, the quantum dot core may have a diameter in a range of about 4.0 nm to about 7.0 nm.

According to an embodiment, a full width at half maximum of the quantum dot core may be less than or equal to about 49 nm. For example, the full width at half maximum of the quantum dot core may be in a range of about 41 nm to about 48 nm.

According to an embodiment, the Group I-III-VI semiconductor compound may include AgInS, AgInS₂, CuInS, CuInS₂, CuGaO₂, AgGaO₂, AgAlO₂, CuInGaS₂, AgInGaS, AgInGaS₂ or a combination thereof. For example, the Group I-III-VI semiconductor compound may include CuInGaS₂. For example, the CuInGaS₂ may be represented by CuInₓGa₁₋ₓS₂ (0≤x≤1).

According to an embodiment, the Group I-III-VI semiconductor compound may include CuInGaS₂, CuInGaS₂, or a combination thereof, and a molar ratio of Cu to the total number of moles of Cu, In, Ga, and S in the quantum dot core may be in a range of about 0.01 to about 0.30. In case that a molar ratio of Cu deviates from the range, a CuInGaS (CIGS) core having a full width at half maximum less than or equal to about 49 nm may not be synthesized.

According to an embodiment, the Group I-III-VI semiconductor compound may include CuInGaS, CuInGaS₂, or a combination thereof, and a molar ratio of In to the total number of moles of Cu, In, Ga, and S in the quantum dot core may be in a range of about 0.10 to about 0.60. In case that the molar ratio of In deviates from the range, a CuInGaS (CIGS) core having a full width at half maximum less than or equal to about 49 nm may not be synthesized.

According to an embodiment, the Group I-III-VI semiconductor compound may include CuInGaS, CuInGaS₂, or a combination thereof, and a molar ratio of Ga to the total number of moles of Cu, In, Ga, and S in the quantum dot core may be in a range of about 0.01 to about 0.30. In case that the molar ratio of Ga deviates from the range, a CuInGaS (CIGS) core having a full width at half maximum less than or equal to about 49 nm may not be synthesized.

According to an embodiment, the Group I-III-VI semiconductor compound may include CuInGaS, CuInGaS₂, or a combination thereof, and a molar ratio of S to the total number of moles of Cu, In, Ga, and S in the quantum dot core may be in a range of about 0.30 to about 0.70. In case that the molar ratio of S deviates from the range, a CuInGaS (CIGS) core having a full width at half maximum less than or equal to about 49 nm may not be synthesized.

According to an embodiment, a blue light exposure stability value of the quantum dot core may be greater than or equal to about 65%.

The blue light exposure stability may be obtained by exposing a solution, which has a concentration at which an optical density is 1 at 450 nm, to a light exposure environment of 200 nit at 450 nm for 2 hours and leaving the solution to obtain a photoluminescence quantum yield (PLQY) value, and the blue light exposure stability may be calculated by following equation.

$$blue light exposure stability value = ( PLQY before exposure ) / ( PLQY after exposure ) \times 100$$

In case that an organic material (for example, a polymer film) is formed on a core surface, photostability may not be secured in case that a shell (for example, a ZnS shell) is grown on a core, and the photostability may be less than 65%.

A quantum dot according to an embodiment may include the quantum dot core and a shell.

The shell may include ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, MgSe, CdS, CdSe, CdTe, ZnSeS, ZnTeS, HgS, HgSe, HgTe, InP, InGaP, or a combination thereof.

In the quantum dot core according to an embodiment, a non-nucleophilic base, a reducing agent, or a combination thereof may be added during a synthetic process, and thus a reaction rate may be accelerated. Therefore, a reaction time may be shortened. As a result, an amount of an organic material (for example, a polymer film derived from a solvent), which may be generated on a core surface due to a long time reaction at high temperature (for example, 320° C.), may be significantly reduced, and the shell may be readily formed on the core surface.

The shell may be formed by a general method. The shell may include one or more layers.

According to an embodiment, a ratio of an inorganic material of the quantum dot may be greater than or equal to about 80 wt %. As described above, since the quantum dot core has a high ratio of an inorganic material, a ratio of an inorganic material in the quantum dot core may also be greater than or equal to about 80 wt %. For example, the ratio of an inorganic material in the quantum dot may be greater than or equal to about 80 wt %.

According to an embodiment, the shell may include ZnS, and a molar ratio of Cu to the total number of moles of the quantum dot may be in a range of about 0.20 to about 0.60. It has been confirmed that in case that molar ratios of Cu, In, Ga, and S in the quantum dot core are as described above and a ZnS shell is formed on the quantum dot core, the molar ratio of Cu does not deviate from the range.

According to an embodiment, the shell may include ZnS, and a molar ratio of In to the total number of moles of the quantum dot may be in a range of about 0.10 to about 0.60. It has been confirmed that in case that molar ratios of Cu, In, Ga, and S in the quantum dot core are as described above and a ZnS shell is formed on the quantum dot core, the molar ratio of In does not deviate from the range.

According to an embodiment, the shell may include ZnS, and a molar ratio of Ga to the total number of moles of the quantum dot may be in a range of about 0.05 to about 0.50. It has been confirmed that in case that molar ratios of Cu, In, Ga, and S in the quantum dot core are as described above and a ZnS shell is formed on the quantum dot core, the molar ratio of Gu does not deviate from the range.

An electronic apparatus according to an embodiment may include a light-emitting device including a first electrode, a second electrode facing the first electrode, and an interlayer which is arranged between the first electrode and the second electrode and includes an emission layer, a thin film transistor, and the quantum dot.

The thin film transistor may include a source electrode and a drain electrode.

The first electrode of the light-emitting device may be electrically connected to at least one of the source electrode and the drain electrode of the thin film transistor.

According to an embodiment, the electronic apparatus may further include a color filter, a color conversion layer, a touch screen layer, a polarizing layer, or a combination thereof.

According to an embodiment, the color conversion layer may include the quantum dot.

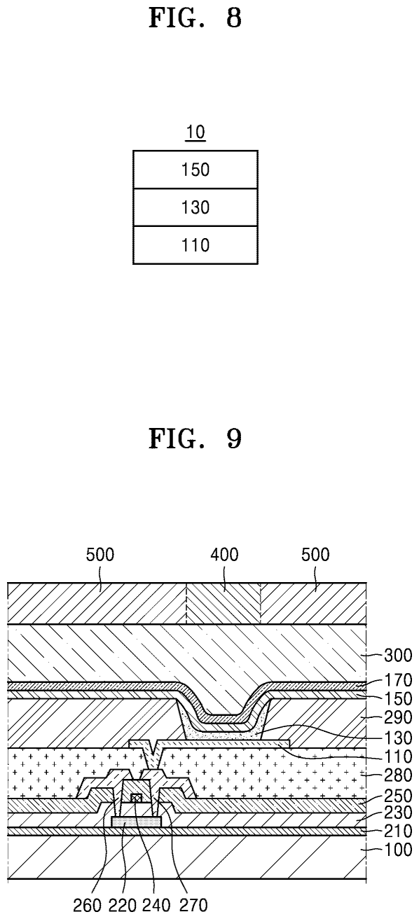

In the specification, the term “interlayer” may be a single layer and/or multiple layers disposed between the first electrode and the second electrode of the light-emitting device.

[Description with Reference to FIG. 8]

FIG. 8 is a schematic cross-sectional view illustrating a light-emitting device 10. The light-emitting device 10 may include a first electrode 110, an interlayer 130, and a second electrode 150.

Hereinafter, a structure of the light-emitting device 10 and a method of manufacturing the same will be described with reference to FIG. 8.

### [First Electrode 110]

A substrate may be disposed below the first electrode 110 or on the second electrode 150 of FIG. 8. As the substrate, a glass substrate or a plastic substrate may be used. In another embodiment, the substrate may be a flexible substrate. For example, the substrate may include a plastic with excellent heat resistance and durability such as polyimide, polyethylene terephthalate (PET), polycarbonate, polyethylene naphtalate, polyarylate (PAR), polyetherimide, or a combination thereof.

The first electrode 110 may be formed, for example, by providing a first electrode material onto the substrate by deposition or sputtering. In case that the first electrode 110 is an anode, a high-work function material that facilitates injection of holes may be used as a material for the first electrode 110.

The first electrode 110 may be a reflective electrode, a semi-transmissive electrode, or a transmissive electrode. In order to form a transparent first electrode 110, the first electrode 110 may include indium tin oxide (ITO), indium zinc oxide (IZO), tin oxide (SnO₂), zinc oxide (ZnO), or a combination thereof. In another embodiment, in order to form a semi-transparent or a reflective first electrode 110, the first electrode 110 may include magnesium (Mg), silver (Ag), aluminum (Al), aluminum-lithium (Al—Li), calcium (Ca), magnesium-indium (Mg—In), magnesium-silver (Mg—Ag), or a combination thereof.

The first electrode 110 may have a structure consisting of a layer or a structure including multiple layers. For example, the first electrode 110 may have a three-layer structure of ITO/Ag/ITO.

### [Interlayer 130]

The interlayer 130 may be disposed on the first electrode 110. The interlayer 130 may include an emission layer.

The interlayer 130 may further include a hole transport region disposed between the first electrode 110 and the emission layer and an electron transport region disposed between the emission layer and the second electrode 150.

In addition to various organic materials, the interlayer 130 may include a metal-containing compound such as an organometallic compound and an inorganic material such as a quantum dot.

In an embodiment, the interlayer 130 may include two or more emission layers sequentially stacked between the first electrode 110 and the second electrode 150 and a charge generation layer disposed between the two emission layers. In case that the interlayer 130 includes an emission layer and a charge generation layer as described above, the light-emitting device 10 may be a tandem light-emitting device.

### [Hole Transport Region in Interlayer 130]

The hole transport region may have a structure consisting of a single material, a structure consisting of a layer including different materials, or a structure including multiple layers including different materials.

The hole transport region may include a hole injection layer, a hole transport layer, an emission auxiliary layer, an electron blocking layer, or a combination thereof.

For example, the hole transport region may have a multi-layer structure such as a hole injection layer/hole transport layer structure, a hole injection layer/hole transport layer/emission auxiliary layer structure, a hole injection layer/emission auxiliary layer structure, or a hole injection layer/hole transport layer/electron blocking layer structure, wherein the layers constituting the structure may be sequentially stacked from the first electrode 110 in its respective stated order, but the structure of the hole transport region is not limited thereto.

The hole transport region may include a compound represented by Formula 201, a compound represented by Formula 202, or a combination thereof:

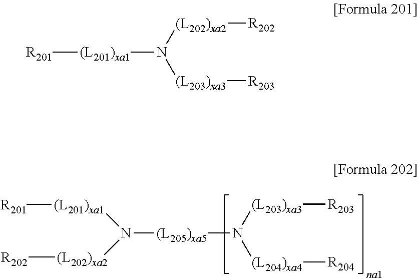

In Formula 201 and Formula 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may be optionally linked to each other by a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (for example, a carbazole group) unsubstituted or substituted with at least one R₁₀ₐ,
R₂₀₃ and R₂₀₄ may be optionally linked to each other by a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and
na1 may be an integer from 1 to 4.

A thickness of the hole transport region may be in a range of about 50 Å to about 10,000 Å. For example, the thickness of the hole transport region may be in a range of about 100 Å to about 4,000 Å. In case that the hole transport region includes a hole injection layer, a hole transport layer, or a combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å, and the thickness of the hole transport layer may be in a range of about 100 Å to about 1,500 Å. In case that the thicknesses of the hole transport region, the hole injection layer, and the hole transport layer satisfy the ranges described above, satisfactory hole transport characteristics may be obtained without a substantial increase in driving voltage.

The emission auxiliary layer may be a layer that serves to increase light emission efficiency by compensating for an optical resonance distance according to a wavelength of light emitted from the emission layer, and the electron blocking layer may be a layer that serves to prevent electrons from leaking from the emission layer to the hole transport region. A material that may be included in the hole transport region described above may be included in the emission auxiliary layer and the electron blocking layer.

### [P-Dopant]

In addition to the materials described above, the hole transport region may include a charge-generating material to improve conductivity. The charge-generating material may be uniformly or non-uniformly dispersed (for example, in the form of a single layer consisting of a charge-generating material) in the hole transport region.

The charge-generating material may be, for example, a p-dopant.

For example, a lowest unoccupied molecular orbital (LUMO) energy level of the p-dopant may be less than or equal to about −3.5 eV.

According to an embodiment, the p-dopant may include a quinone derivative, a cyano group-containing compound, an element EL1 and element EL2-containing compound, or a combination thereof.

Examples of the quinone derivative may include TCNQ, F4-TCNQ, and the like.

Examples of the cyano group-containing compound may include HAT-CN, a compound represented by Formula 221, and the like.

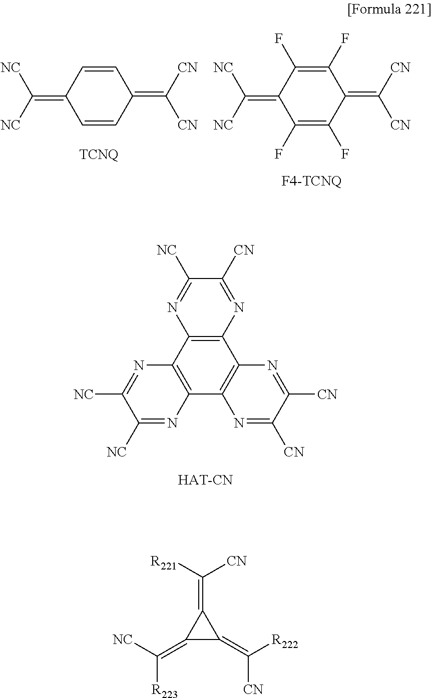

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and
at least one of R₂₂₁ to R₂₂₃ may independently be: a cyano group; —F; —Cl; —Br; —I; a C₁-C₂₀ alkyl group substituted with a cyano group, —F, —Cl, —Br, —I, or a combination thereof; or a C₃-C₆₀ carbocyclic group or a C₁-C₆₀ heterocyclic group substituted with a cyano group, —F, —Cl, —Br, —I, or a combination thereof.

In an element EL1 and element EL2-containing compound, element EL1 may be a metal, a metalloid, or a combination thereof, and element EL2 may be a non-metal, a metalloid, or a combination thereof.

Examples of a metal may include an alkali metal (for example, lithium (Li), sodium (Na), potassium (K), rubidium (Rb), or cesium (Cs)), an alkali earth metal (for example, beryllium (Be), magnesium (Mg), calcium (Ca), strontium (Sr), and barium (Ba)), a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), and gold (Au)), a post-transition metal (for example, zinc (Zn), indium (In), and tin (Sn)), a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu)), and the like.

Examples of a metalloid may include silicon (Si), antimony (Sb), tellurium (Te), and the like.

Examples of a non-metal may include oxygen (O), a halogen (for example, F, Cl, Br, or I), and the like.

For example, an element EL1 and element EL2-containing compound may include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), a metal telluride, or any combination thereof.

Examples of a metal oxide may include a tungsten oxide (for example, WO, W₂O₃, WO₂, WO₃, or W₂O₅), a vanadium oxide (for example, VO, V₂O₃, VO₂, or V₂O₅), a molybdenum oxide (MoO, Mo₂O₃, MoO₂, MoO₃, Mo₂O₅, or the like), a rhenium oxide (for example, ReO₃), and the like.

Examples of a metal halide may include an alkali metal halide, an alkali earth metal halide, a transition metal halide, a post-transition metal halide, a lanthanide metal halide, and the like.

Examples of an alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of an alkali earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of a transition metal halide may include a titanium halide (for example, TiF₄, TiCl₄, TiBr₄, or TiI₄), a zirconium halide (for example, ZrF₄, ZrCl₄, ZrBr₄, or ZrI₄), a hafnium halide (for example, HfF₄, HfCl₄, HfBr₄, or HfI₄), a vanadium halide (for example, VF₃, VCl₃, VBr₃, or VI₃), a niobium halide (for example, NbF₃, NbCl₃, NbBr₃, or NbI₃), a tantalum halide (for example, TaF₃, TaCl₃, TaBr₃, or TaI₃), a chromium halide (for example, CrF₃, CrCl₃, CrBr₃, or CrI₃), a molybdenum halide (for example, MoF₃, MoCl₃, MoBr₃, or MoI₃), a tungsten halide (for example, WF₃, WCl₃, WBr₃, or WI₃), a manganese halide (for example, MnF₂, MnCl₂, MnBr₂, or MnI₂), a technetium halide (for example, TcF₂, TcCl₂, TcBr₂, or TcI₂), a rhenium halide (for example, ReF₂, ReCl₂, ReBr₂, or ReI₂), an iron halide (for example, FeF₂, FeCl₂, FeBr₂, or FeI₂), a ruthenium halide (for example, RuF₂, RuCl₂, RuBr₂, or RuI₂), an osmium halide (for example, OsF₂, OsCl₂, OsBr₂, or OsI₂), a cobalt halide (for example, CoF₂, CoCl₂, CoBr₂, or CoI₂), a rhodium halide (for example, RhF₂, RhCl₂, RhBr₂, or RhI₂), an iridium halide (for example, IrF₂, IrCl₂, IrBr₂, or IrI₂), a nickel halide (for example, NiF₂, NiCl₂, NiBr₂, or NiI₂), a palladium halide (for example, PdF₂, PdCl₂, PdBr₂, or PdI₂), a platinum halide (for example, PtF₂, PtCl₂, PtBr₂, or PtI₂), a copper halide (for example, CuF, CuCl, CuBr, or CuI), a silver halide (for example, AgF, AgCl, AgBr, or AgI), a gold halide (for example, AuF, AuCl, AuBr, or AuI), and the like.

Examples of a post-transition metal halide may include a zinc halide (for example, ZnF₂, ZnCl₂, ZnBr₂, or ZnI₂), an indium halide (for example, Inks), a tin halide (for example, SnI₂), and the like.

Examples of a lanthanide metal halide may include YbF, YbF₂, YbF₃, SmF₃, YbCl, YbCl₂, YbCl₃ SmCl₃, YbBr, YbBr₂, YbBr₃ SmBr₃, YbI, YbI₂, YbI₃, SmI₃, and the like.

Examples of a metalloid halide may include an antimony halide (for example, SbCl₅), and the like.

Examples of a metal telluride may include an alkali metal telluride (for example, Li₂Te, Na₂Te, K₂Te, Rb₂Te, or Cs₂Te), an alkali earth metal telluride (for example, BeTe, MgTe, CaTe, SrTe, or BaTe), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, or Au₂Te), a post-transition metal telluride (for example, ZnTe), a lanthanide metal telluride (for example, LaTe, CeTe, PrTe, NdTe, PmTe, EuTe, GdTe, TbTe, DyTe, HoTe, ErTe, TmTe, YbTe, or LuTe), and the like.

### [Emission Layer of Interlayer 130]

In case that the light-emitting device 10 is a full-color light-emitting device, the emission layer may be patterned into a red emission layer, a green emission layer, and/or a blue emission layer for each individual subpixel. In another embodiment, the emission layer may have a structure in which two or more layers of a red emission layer, a green emission layer, and a blue emission layer are stacked to be contacting each other or spaced apart from each other or a structure in which two or more materials of a red emission material, a green emission material, and a blue emission material are mixed without separation of layers, thereby emitting white light.

A thickness of the emission layer may be in a range of about 100 Å to about 1,000 Å. For example, the thickness of the emission layer may be in a range of about 200 Å to about 600 Å. In case that the thickness of the emission layer satisfies the range described above, excellent emission characteristics may be exhibited without a substantial increase in driving voltage.

### [Quantum Dot]

An energy band gap may be controlled by controlling a size of a quantum dot, and thus light with various wavelengths may be obtained in a quantum dot emission layer. Therefore, by using quantum dots with different sizes, a light-emitting device that emits light with different wavelengths may be implemented. For example, a size of a quantum dot may be selected to emit red, green, and/or blue light. The quantum dot may have a size such that light with various colors are combined to emit white light.

The emission layer may include a quantum dot according to an embodiment.

The quantum dot may be defined as described above.

The quantum dot may be in a form of a spherical particle, a pyramidal particle, a multi-arm particle, a cubic nanoparticle, a nanotube particle, a nanowire particle, a nanofiber particle, or a nanoplate particle.

### [Electron Transport Region of Interlayer 130]

The electron transport region may have a structure consisting of a single material, a structure consisting of a layer including different materials, or a structure including multiple layers including different materials.

The electron transport region may include a hole blocking layer, an electron transport layer, an electron injection layer, or a combination thereof.

For example, the electron transport region may have an electron transport layer/electron injection layer structure or a hole blocking layer/electron transport layer/electron injection layer structure, wherein the layers constituting the structure are sequentially stacked from the emission layer in its respective stated order, but the structure of the electron transport region is not limited thereto.

The electron transport region (for example, the hole blocking layer or the electron transport layer in the electron transport region) may include a metal-free compound including at least one π electron-deficient nitrogen-containing C₁-C₆₀ cyclic group.

For example, the electron transport region may include a compound represented by Formula 601 below.

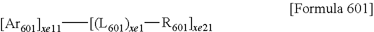

In Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be for the same as described herein with respect to Q₁,
xe21 may be 1, 2, 3, 4, or 5, and
at least one of Ar₆₀₁, L₆₀₁, and R₆₀₁ may independently be a π electron-deficient nitrogen-containing C₁-C₆₀ cyclic group unsubstituted or substituted with at least one R₁₀ₐ.

In an embodiment, in Formula 601, in case that xe11 is 2 or more, two or more of Ar₆₀₁ may be linked to each other by a single bond.

In an embodiment, in Formula 601, Ar₆₀₁ may be a substituted or unsubstituted anthracene group.

In an embodiment, the electron transport region may include a compound represented by Formula 601-1:

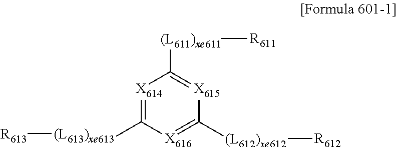

In Formula 601-1,
X₆₁₄ may be N or C(R₆₁₄), X₆₁₅ may be N or C(R₆₁₅), X₆₁₆ may be N or C(R₆₁₆), at least one of X₆₁₄ to X₆₁₆ may each be N,
L₆₁₁ to L₆₁₃ may each independently be the same as described herein with respect to L₆₀₁,
xe611 to xe613 may each independently be the same as described herein with respect to xe1,
R₆₁₁ to R₆₁₃ may each independently be for the same as described herein with respect to R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formula 601 and Formula 601-1, xe1 and xe611 to xe613 may each independently be 0, 1, or 2.

A thickness of the electron transport region may be in a range of about 100 Å to about 5,000 Å. For example, the thickness of the electron transport region may be in a range of about 160 Å to about 4,000 Å. In case that the electron transport region includes a hole blocking layer, an electron transport layer, or a combination thereof, thicknesses of the hole blocking layer and the electron transport layer may each independently be in a range of about 20 Å to about 1,000 Å, and the thickness of the electron transport layer may be in a range of about 100 Å to about 1,000 Å. For example, the thicknesses of the hole blocking layer and the electron transport layer may each independently be in a range of about 30 Å to about 300 Å, and the thickness of the electron transport layer may be in a range of about 150 Å to about 500 Å. In case that the thicknesses of the hole blocking layer and/or the electron transport layer satisfy the range described above, satisfactory electron transport characteristics may be obtained without a substantial increase in operating voltage.

The electron transport region (for example, an electron transport layer in the electron transport region) may further include a metal-containing material in addition to the materials described above.

A metal-containing material may include an alkali metal complex, an alkali earth metal complex, or a combination thereof. A metal ion of the alkali metal complex may be a Li ion, a Na ion, a K ion, a Rb ion, or a Cs ion, and a metal ion of the alkali earth metal complex may be a Be ion, a Mg ion, a Ca ion, a Sr ion, or a Ba ion. For example, the metal-containing material may be a Li-based or Ca-based compound. Ligands coordinated to the metal ions of the alkali metal complex and the alkali earth metal complex may each independently include hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzoimidazole, hydroxyphenylbenzothiazole, bipyridine, phenanthroline, cyclopentadiene, or a combination thereof.

For example, a metal-containing material may include a Li complex. The Li complex may include, for example, Compound ET-D1 (LiQ) or ET-D2:

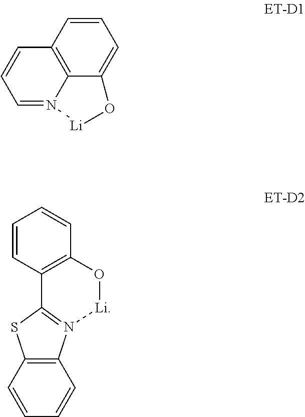

The electron transport region may include an electron injection layer configured to facilitate the injection of electrons from the second electrode 150. The electron injection layer may be in direct contact with the second electrode 150.

The electron injection layer may have a structure consisting of a material, a structure consisting of a layer including different materials, or a structure including multiple layers including different materials.

The electron injection layer may include an alkali metal, an alkali earth metal, a rare earth metal, an alkali metal-containing compound, an alkali earth metal-containing compound, a rare earth metal-containing compound, an alkali metal complex, an alkali earth metal complex, a rare earth metal complex, or any combination thereof.

The alkali metal may include Li, Na, K, Rb, Cs, or a combination thereof. The alkali earth metal may include Mg, Ca, Sr, Ba, or a combination thereof. The rare earth metal may include Sc, Y, Ce, Tb, Yb, Gd, or a combination thereof.

The alkali metal-containing compound, the alkali earth metal-containing compound, and the rare earth metal-containing compound may each include an oxide, a halide (for example, a fluoride, a chloride, a bromide, or an iodide), or a telluride of each of the alkali metal, the alkali earth metal, and the rare earth metal, or a combination thereof

The alkali metal-containing compound may include an alkali metal oxide such as Li₂O, Cs₂O, or K₂O, an alkali metal halide such as LiF, NaF, CsF, KF, LiI, NaI, CsI, or KI, or a combination thereof. The alkali earth metal-containing compound may include an alkaline earth metal compound such as BaO, SrO, CaO, BaₓSr₁₋ₓO, wherein x is a real number satisfying 0<x<1, or BaₓCa₁₋ₓO, wherein x is a real number satisfying 0<x<1. The rare earth metal-containing compound may include YbF₃, ScF₃, Sc₂O₃, Y₂O₃, Ce₂O₃, GdF₃, TbF₃, YbI₃, ScI₃, TbI₃, or a combination thereof. The rare earth metal-containing compound may include a lanthanide metal telluride. Examples of a lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkali earth metal complex, and the rare earth metal complex may include: an alkali metal ion, an alkali earth metal ion, or a rare earth metal ion as described above; and a ligand bonded to a metal ion, for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzoimidazole, hydroxyphenylbenzothiazole, bipyridine, phenanthroline, cyclopentadiene, or any combination thereof.

The electron injection layer may consist only of an alkali metal, an alkali earth metal, a rare earth metal, an alkali metal-containing compound, an alkali earth metal-containing compound, a rare earth metal-containing compound, an alkali metal complex, an alkali earth metal complex, a rare earth metal complex, or a combination thereof as described above or may further include an organic material (for example, the compound represented by Formula 601).

According to an embodiment, the electron injection layer may consist of: an alkali metal-containing compound (for example, an alkali metal halide); or the electron injection layer may consist of an alkali metal-containing compound (for example, an alkali metal halide), and an alkali metal, an alkali earth metal, a rare earth metal, or a combination thereof. For example, the electron injection layer may be a KI:Yb co-deposition layer, a RbI:Yb co-deposition layer, or the like.

In case that the electron injection layer further includes an organic material, the alkali metal, the alkali earth metal, the rare earth metal, the alkali metal-containing compound, the alkali earth metal-containing compound, the rare earth metal-containing compound, the alkali metal complex, the alkali earth metal complex, the rare earth metal complex, or a combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. In case that the thickness of the electron injection layer satisfies the range described above, satisfactory electron injection characteristics may be obtained without a substantial increase in driving voltage.

### [Second Electrode 150]

The second electrode 150 may be disposed on the interlayer 130 as described above. The second electrode 150 may be a cathode which is an electron injection electrode, and may include a metal, an alloy, an electrically conductive compound, or a combination thereof having a low work function.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layer structure or a multi-layer structure having multiple layers.

### [Capping Layer]

The light-emitting device 10 may include a first capping layer outside the first electrode 110, and/or a second capping layer may be disposed outside the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in the emission layer in the interlayer 130 of the light-emitting device 10 may be emitted to the outside through the first electrode 110, which may be a semi-transmissive electrode or a transmissive electrode, and through the first capping layer. Light generated in the emission layer in the interlayer 130 of the light-emitting device 10 may be emitted to the outside through the second electrode 150, which may be a semi-transmissive electrode or a transmissive electrode, and through the second capping layer.

The first capping layer and the second capping layer may each serve to improve external emission efficiency by the principle of constructive interference. Accordingly, the light extraction efficiency of the light-emitting device 10 may be increased, and thus the emission efficiency of the light-emitting device 10 may be improved.

Each of the first capping layer and the second capping layer may include a material having a refractive index (at 589 nm) greater than or equal to about 1.6.

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may independently include a carbocyclic compound, a heterocyclic compound, an amine group-containing compound, a porphine derivative, a phthalocyanine derivative, a naphthalocyanine derivative, an alkali metal complex, an alkali earth metal complex, or a combination thereof. In an embodiment, the carbocyclic compound, the heterocyclic compound, and the amine group-containing compound may be optionally substituted with a substituent including O, N, S, Se, Si, F, Cl, Br, I, or a combination thereof. According to an embodiment, at least one of the first capping layer and the second capping layer may independently include an amine group-containing compound.

For example, at least one of the first capping layer and the second capping layer may independently include the compound represented by Formula 201, the compound represented by Formula 202, or a combination thereof.

According to another embodiment, at least one of the first capping layer and the second capping layer may independently include one of Compounds CP1 to CP6, β-NPB, or a compound thereof:

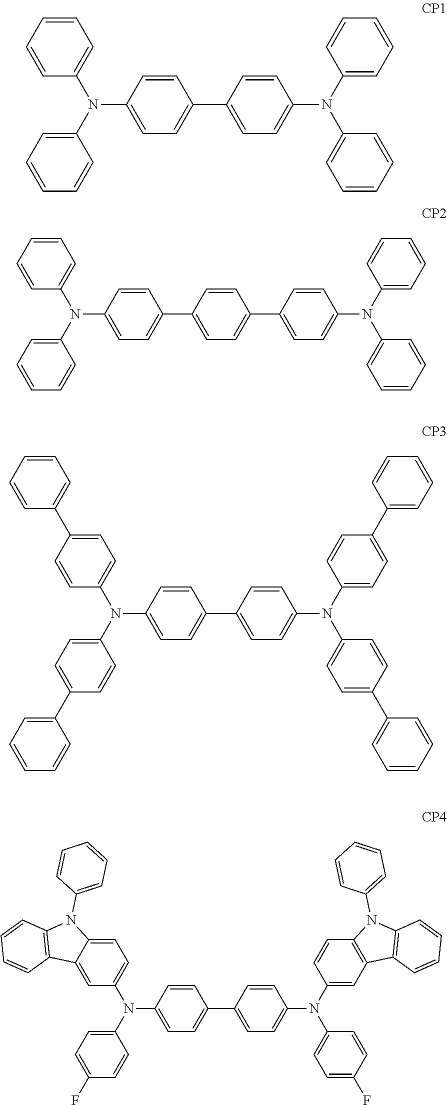 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

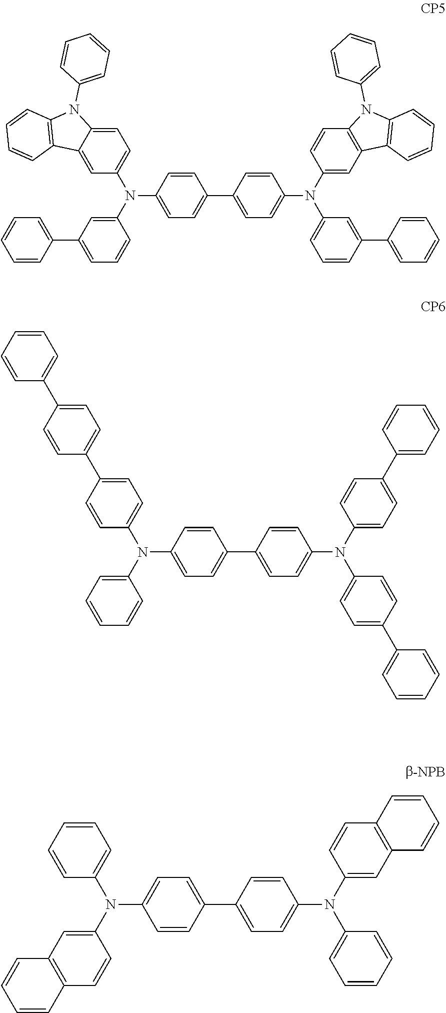 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### [Electronic Apparatus]

The light-emitting device may be included in various electronic apparatuses. In an embodiment, an electronic apparatus including the light-emitting device may be a light-emitting apparatus, an authentication apparatus, or the like.

In addition to the light-emitting device, the electronic apparatus (for example, a light-emitting apparatus) may further include a color filter, a color conversion layer, or a color filter and a color conversion layer. The color filter and/or the color conversion layer may be disposed in at least one traveling direction of light emitted from the light-emitting device. For example, light emitted from the light-emitting device may be blue light. The light-emitting device may be defined as described above. According to an embodiment, the color conversion layer may include a quantum dot. The quantum dot may be, for example, the quantum dot described herein.

The electronic apparatus may include a first substrate. The first substrate may include multiple subpixels, the color filter may include multiple color filter regions respectively corresponding to the subpixels, and the color conversion layer may include multiple color conversion regions respectively corresponding to the subpixels.

A pixel definition film may be disposed between the subpixels to define each subpixel.

The color filter may further include multiple color filter regions and a light blocking pattern disposed between the color filter regions, and the color conversion layer may further include multiple color conversion regions and a light blocking pattern disposed between the color conversion regions.

The color filter regions (or the color conversion regions) may include a first region configured to emit first color light, a second region configured to emit second color light, and/or a third region configured to emit third color light, and the first color light, the second color light, and/or the third color light may have different maximum emission wavelengths. For example, the first color light may be red light, the second color light may be green light, and the third color light may be blue light. For example, the color filter regions (or the color conversion regions) may include quantum dots. For example, the first region may include red quantum dots, the second region may include green quantum dots, and the third region may not include quantum dots. The quantum dot may be as defined herein. Each of the first region, the second region, and/or the third region may further include a scatterer.

In an embodiment, the light-emitting device may be configured to emit first light, the first region may be configured to absorb the first light to emit 1-1 color light, the second region may be configured to absorb the first light to emit 2-1 color light, and the third region may be configured to absorb the first light to emit 3-1 color light. The 1-1 color light, the 2-1 color light, and the 3-1 color light may have different maximum emission wavelengths. For example, the first light may be blue light, the 1-1 color light may be red light, the 2-1 color light may be green light, and the 3-1 color light may be blue light.

The electronic apparatus may further include a thin film transistor in addition to the light-emitting device described above. The thin film transistor may include a source electrode, a drain electrode, and an active layer, and one of the source electrode and the drain electrode may be electrically connected to one of a first electrode and a second electrode of the light-emitting device.

The thin film transistor may further include a gate electrode, a gate insulating film, and the like.

The active layer may include crystalline silicon, amorphous silicon, an organic semiconductor, an oxide semiconductor, or the like.

The electronic apparatus may further include a sealing portion configured to seal the light-emitting device. The sealing portion may be disposed between the color filter and/or color conversion layer and the light-emitting device. The encapsulation portion may allow light from the light-emitting device to be extracted to the outside and may simultaneously prevent ambient air and moisture from penetrating into the light-emitting device. The sealing portion may be a sealing substrate including a transparent glass substrate or a plastic substrate. The sealing portion may be a thin film encapsulation layer including one or more organic layers and/or one or more inorganic layers. In case that the sealing portion is a thin film encapsulation layer, the electronic apparatus may be flexible.

On the sealing portion, in addition to the color filter and/or the color conversion layer, various functional layers may be additionally disposed according to the use of the electronic apparatus. Examples of the functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus configured to authenticate an individual by using biometric information of a living body (for example, fingertips, pupils, or the like).

The authentication apparatus may further include a biometric information collection means in addition to the light-emitting device described above.

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement apparatuses, pulse wave measurement apparatuses, electrocardiogram displays, ultrasonic diagnostic apparatuses, or endoscope displays), fish finders, various measuring instruments, meters (for example, meters for a vehicle, an aircraft, and a vessel), projectors, and the like.

[Description with Reference to FIG. 9]

FIG. 9 is a schematic cross-sectional view of an electronic apparatus according to an embodiment.

The electronic apparatus of FIG. 9 may include a substrate 100, a thin film transistor, a light-emitting device, and an encapsulation portion 300 configured to seal the light-emitting device.

The substrate 100 may be a flexible substrate, a glass substrate, or a metal substrate. A buffer layer 210 may be disposed on the substrate 100. The buffer layer 210 may prevent the penetration of impurities through the substrate 100 and may serve to provide a flat surface to an upper portion of the substrate 100.

The thin film transistor may be disposed on the buffer layer 210. The thin film transistor may include an active layer 220, a gate electrode 240, a source electrode 260, and a drain electrode 270.

The active layer 220 may include an inorganic semiconductor such as silicon or polysilicon, an organic semiconductor, or an oxide semiconductor and may include a source region, a drain region, and a channel region.

A gate insulating film 230 may be disposed on the active layer 220 to insulate the active layer 220 from the gate electrode 240, and the gate electrode 240 may be disposed on the gate insulating film 230.

An interlayer insulating film 250 may be disposed on the gate electrode 240. The interlayer insulating film 250 may be disposed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be disposed on the interlayer insulating film 250. The interlayer insulating film 250 and the gate insulating film 230 may be formed to expose a source region and a drain region of the active layer 220, and the source electrode 260 and the drain electrode 270 may respectively contact the exposed source region and drain region of the active layer 220.

The thin film transistor described above may be electrically connected to the light-emitting device to drive the light-emitting device and may be covered and protected with a passivation layer 280. The passivation layer 280 may include an inorganic insulating film, an organic insulating film, or a combination thereof. The light-emitting device may be provided on the passivation layer 280. The light-emitting device may include a first electrode 110, an interlayer 130, and a second electrode 150.

The first electrode 110 may be disposed on the passivation layer 280. The passivation layer 280 may expose a certain region without covering the entire drain electrode 270, and the first electrode 110 may be connected to the exposed drain electrode 270.

A pixel definition film 290 including an insulating material may be disposed on the first electrode 110. The pixel definition film 290 may expose a portion of the first electrode 110, and the interlayer 130 may be formed in the exposed portion. The pixel definition film 290 may be a polyimide or polyacrylic-based organic film. Although not shown in FIG. 9, at least some layers of the interlayer 130 may extend to an upper portion of the pixel definition film 290 to be provided in the form of a common layer.

The second electrode 150 may be disposed on the interlayer 130, and a capping layer 170 may be further included on the second electrode 150. The capping layer 170 may be formed to cover the second electrode 150.

The encapsulation portion 300 may be disposed on the capping layer 170. The encapsulation portion 300 may be disposed on the light-emitting device to serve to protect the light-emitting device from moisture and/or oxygen. The encapsulation portion 300 may include an inorganic film including silicon nitride (SiNₓ), silicon oxide (SiOₓ), ITO, IZO, or any combination thereof, an organic film including PET, polyethylene naphthalate, polycarbonate, polyimide, polyethylene sulfonate, polyoxymethylene, PAR, hexamethyldisiloxane, an acrylic resin (for example, polymethyl methacrylate or a polyacrylic acid), an epoxy-based resin (for example, aliphatic glycidyl ether (AGE)), or any combination thereof, or a combination of an inorganic film and an organic film.

A light shielding pattern 500 and a functional region 400 may be disposed on the encapsulation portion 300. The functional region 400 may be a color filter region, a color conversion region, or a combination of a color filter region and a color conversion region.

According to an embodiment, the functional region 400 may include the quantum dot according to an embodiment.

According to an embodiment, the light-emitting device included in the light-emitting apparatus of FIG. 9 may be a tandem light-emitting device.

### [Manufacturing Method]

Each layer included in the hole transport region, the emission layer, and each layer included in the electron transport region may each be formed in a certain region by using a method such as vacuum deposition, spin coating, casting, langmuir-blodgett (LB) deposition, ink-jet printing, laser-printing, and laser-induced thermal imaging (LITI).

In case that each layer included in the hole transport region, the emission layer, and each layer included in the electron transport region are each formed by spin coating, coating conditions may be selected in consideration of a material to be included in a layer to be formed and a structure of the layer to be formed, for example, with a coating speed in a range of about 2,000 rpm to about 5,000 rpm and a heat treatment temperature in a range of about 80° C. to about 200° C.

### Definitions of Terms

As used herein, the term “C₃-C₆ carbocyclic group” may be a cyclic group having 3 to 60 carbon atoms the only ring-forming atoms, and the term “C₁-C₆₀ heterocyclic group” may be a cyclic group having 1 to 60 carbon atoms and further including at least one heteroatom as a ring-forming atom in addition to a carbon atom. Each of the C₃-C₆₀ carbocyclic group and the C₁-C₆₀ heterocyclic group may be a monocyclic group having one ring or a polycyclic group in which two or more rings are condensed with each other. For example, the number of ring-forming atoms of the C₁-C₆₀ heterocyclic group may be in a range of 3 to 61.

As used herein, the term “cyclic group” be a C₃-C₆₀ carbocyclic group and the C₁-C₆₀ heterocyclic group.

As used herein, the term “π electron-rich C₃-C₆₀ cyclic group” may be a cyclic group that has 3 to 60 carbon atoms and may not include *—N═*′ as a ring-forming moiety, and the term “π electron-deficient nitrogen-containing C₁-C₆₀ cyclic group” may be a heterocyclic group that has 1 to 60 carbon atoms and may include *—N═*′ as a ring-forming moiety.

In an embodiment, a C₃-C₆₀ carbocyclic group may be a T1 group T1 or a group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group).

A C₁-C₆₀ heterocyclic group may be a T2 group, a group in which two or more T2 groups are condensed with each other, or a group in which one or more T2 groups and one or more T1 groups are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group).

A π electron-rich C₃-C₆₀ cyclic group may be a T1 group, a group in which two or more T1 groups are condensed with each other, a T3 group, a group in which two or more T3 groups are condensed with each other, or a group in which one or more T3 groups and one or more T1 groups are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, or a benzothienodibenzothiophene group).

A π electron-deficient nitrogen-containing C₁-C₆₀ cyclic group may be a T4 group, a group in which two or more T4 group are condensed with each other, a group in which one or more T4 groups and one or more T1 groups are condensed with each other, a group in which one or more T4 groups and one or more T3 groups are condensed with each other, or a group in which one or more T4 groups, one or more T1 groups, and one or more T3 groups are condensed with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group).

The T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group.

The T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group.

The T3 group may be a furan group, a thiophene group, a 1H-pyrrole group, a silole group, or a borole group.

The T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

As used herein, the term “cyclic group,” “C₃-C₆₀ carbocyclic group,” “C₁-C₆₀ heterocyclic group,” “π electron-rich C₃-C₆₀ cyclic group,” or “π electron-deficient nitrogen-containing C₁-C₆₀ cyclic group” may each be a group condensed to a cyclic group, a monovalent group, or a multivalent group (for example, a divalent group, a trivalent group, or a tetravalent group) according to a structure of a formula in which the term is used. For example, a “benzene group” may be a benzo group, a phenyl group, a phenylene group, or the like, which may be understood by those skilled in the art according to a structure of a formula including the “benzene group.”

For example, examples of a monovalent C₃-C₆₀ carbocyclic group and a monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a non-aromatic hetero condensed hetero-polycyclic group, and examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed hetero-polycyclic group.

As used herein, the term “C₁-C₆₀ alkyl group” may be a linear or branched aliphatic hydrocarbon monovalent group having 1 to 60 carbon atoms, and specific examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, a tert-decyl group, and the like. As used herein, the term “C₁-C₆₀ alkylene group” may be a divalent group having the same structure as the C₁-C₆₀ alkyl group.

As used herein, the term “C₂-C₆₀ alkenyl group” may be a monovalent hydrocarbon group including one or more carbon-carbon double bonds in the middle or at a terminus of a C₂-C₆₀ alkyl group, and specific examples thereof may include an ethenyl group, a propenyl group, a butenyl group, and the like. As used herein, the term “C₂-C₆₀ alkenyl group” may be a divalent group having a same structure as the C₂-C₆₀ alkenyl group.

As used herein, the term “C₂-C₆₀ alkynyl group” may be a monovalent hydrocarbon group including one or more carbon-carbon triple bonds in the middle or at a terminal of a C₂-C₆₀ alkyl group, and specific examples thereof may include an ethynyl group, a propynyl group, and the like. As used herein, the term “C₂-C₆₀ alkynylene group” may be a divalent group having a same structure as the C₂-C₆₀ alkynyl group.

As used herein, the term “C₁-C₆₀ alkoxy group” may be a monovalent group having a formula of —(OA₁₀₁), wherein A₁₀₁ may be a C₁-C₆₀ alkyl group, and specific examples thereof may include a methoxy group, an ethoxy group, an isopropyloxy group, and the like.

As used herein, the term “C₃-C₁₀ cycloalkyl group” may be a monovalent saturated hydrocarbon cyclic group having 3 to 10 carbon atoms, and specific examples thereof may include a cyclopropyl group, a cyclobutyl group, a cyclopentyl group, a cyclohexyl group, a cycloheptyl group, a cyclooctyl group, adamantanyl, a norbornanyl group (or, a bicyclo[2.2.1]heptyl group), a bicyclo[1.1.1]pentyl group, a bicyclo[2.1.1]hexyl group, a bicyclo[2.2.2]octyl group, and the like. As used herein, the term “C₃-C₁ cycloalkylene group” may be a divalent group having a same structure as the C₃-C₁ cycloalkyl group.

As used herein, the term “C₁-C₁ heterocycloalkyl group” may be a monovalent cyclic group having 1 to 10 carbon atoms and further including at least one heteroatom as a ring-forming atom in addition to carbon atoms, and examples thereof may include a 1,2,3,4-oxatriazolidinyl group, a tetrahydrofuranyl group, a tetrahydrothiophenyl group, and the like. As used herein, the term “C₁-C₁₀ heterocycloalkylene group” may be a divalent group having a same structure as the C₁-C₁₀ heterocycloalkyl group.

As used herein, the term “C₃-C₁₀ cycloalkenyl group” may be a monovalent cyclic group which have 3 to 10 carbon atoms and may have at least one carbon-carbon double bond in a ring thereof but not having aromaticity, and examples thereof may include a cyclopentenyl group, a cyclohexenyl group, a cycloheptenyl group, and the like. As used herein, the term “C₃-C₁₀ cycloalkenylene group” may be a divalent group having a same structure as the C₃-C₁₀ cycloalkenyl group.

As used herein, the term “C₁-C₁₀ heterocycloalkenyl group” may be a monovalent cyclic group which has 1 to 10 carbon atoms, further including at least one heteroatom as a ring-forming atom in addition to carbon atoms, and having at least one double bond in a ring thereof. Examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. As used herein, the term “C₁-C₁₀ heterocycloalkenylene group” may be a divalent group having a same structure as the C₁-C₁₀ heterocycloalkenyl group.

As used herein, the term “C₆-C₆₀ aryl group” may be a monovalent group having a carbocyclic aromatic system which has 6 to 60 carbon atoms, and the term “C₆-C₆₀ arylene group” may be a divalent group having a carbocyclic aromatic system which has 6 to 60 carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. In case that the C₆-C₆₀ aryl group and the C₆-C₆₀ arylene group include two or more rings, the two or more rings may be condensed with each other.

As used herein, the term “C₁-C₆₀ heteroaryl group” may be a monovalent group further including at least one heteroatom as a ring-forming atom in addition to carbon atom and having a heterocyclic aromatic system which has 1 to 60 carbon atoms, and the C₁-C₆₀ heteroarylene group may be a divalent group further including at least one heteroatom as a ring-forming atom in addition to carbon atoms and having a heterocyclic aromatic system which has 1 to 60 carbon atoms. Examples of a C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a naphthyridinyl group, and the like. In case that the C₁-C₆₀ heteroaryl group and the C₁-C₆₀ heteroarylene group include two or more rings, the two or more rings may be condensed with each other.

As used herein, the term “monovalent non-aromatic condensed polycyclic group” may be a monovalent group (for example, having 8 to 60 carbon atoms) in which two or more rings are condensed with each other, which includes only carbon as a ring-forming atom, and of which the entire molecule has non-aromaticity. Examples of the monovalent non-aromatic condensed polycyclic group may include an indenyl group, a fluorenyl group, a spiro-bifluorenyl group, a benzofluorenyl group, an indenophenanthrenyl group, an indenoanthracenyl group, and the like. As used herein, the term “divalent non-aromatic condensed polycyclic group” may be a divalent group having a same structure as the monovalent non-aromatic condensed polycyclic group.

As used herein, the term “monovalent non-aromatic condensed heteropolycyclic group” may be a monovalent group (for example, having 1 to 60 carbon atoms) in which two or more rings are condensed with each other, which further includes at least one heteroatom as a ring-forming atom in addition to carbon atoms, and of which the entire molecule has no aromaticity. Examples of the monovalent non-aromatic condensed hetero-polycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. As used herein, the term “divalent non-aromatic condensed hetero-polycyclic group” may be a divalent group having a same structure as the monovalent non-aromatic condensed hetero-polycyclic group.

As used herein, the term “C₆-C₆₀ aryloxy group” may be a group represented by —O(A₁₀₂), wherein A₁₀₂ may be a C₆-C₆₀ aryl group, and the C₆-C₆₀ arylthio group may be a group represented by —S(A₁₀₃), wherein A₁₀₃ may be a C₆-C₆₀ aryl group.

As used herein, the term “C₇-C₆₀ arylalkyl group” may be a group represented by -(A₁₀₄)(A₁₀₅), wherein A₁₀₄ may be a C₁-C₅₄ alkylene group and A₁₀₅ may be a C₆-C₅₉ aryl group, and as used herein, the term “C₂-C₆₀ heteroarylalkyl group” may be a group represented by -(A₁₀₆)(A₁₀₇), wherein A₁₀₆ may be a C₁-C₅₉ alkylene group and A₁₀₇ may be a C₁-C₅₉ heteroaryl group.

As used herein, the group “R₁₀ₐ” may be:
Deuterium (-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

As used herein, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or a combination thereof.

As used herein, the term “heteroatom” may be any atom other than a carbon atom or a hydrogen atom. Examples of a heteroatom may include O, S, N, P, Si, B, Ge, Se, or a combination thereof.

As used herein, the term “third-row transition metal” may be hafnium (Hf), tantalum (Ta), tungsten (W), rhenium (Re), osmium (Os), iridium (Ir), platinum (Pt), gold (Au), or the like.

As used herein, the term “Ph” may be a phenyl group, the term “Me” may be a methyl group, the term “Et” may be an ethyl group, the term “ter-Bu” or “Bu^{t}” may be a tert-butyl group, and the term “OMe” may be a methoxy group.

As used herein, the term “biphenyl group” may be a “phenyl group substituted with a phenyl group.” For example, “biphenyl group” may be a “substituted phenyl group” of which a substituent is a “C₆-C₆₀ aryl group.”

As used herein, the term “terphenyl group” may be a “phenyl group substituted with a biphenyl group.” For example, the “terphenyl group” may be a “substituted phenyl group” of which a substituent is a “C₆-C₆₀ aryl group substituted with a C₆-C₆₀ aryl group.”

In the definition of a substituent, the number of carbon atoms is merely an example. For example, in a C₁-C₆₀ alkyl group, C₆₀ is merely an example, and the definition of an alkyl group may be equally applied to a C₁-C₂₀ alkyl group. The same may be applied to other cases.

As used herein, unless otherwise defined, the symbols ″* and *′″ may each be a bonding site with an adjacent atom in a corresponding formula.

Hereinafter, a compound and a light-emitting device according to an embodiment will be described in more detail with reference to the Examples.

### EXAMPLES

### Preparation of Quantum Dot Core

### Example 1

200 ml of solvents, oleylamine and octadecene (volume ratio=1:1), were put into a 300 ml flask, and 1.5 mmol of CuBr₃, 1.0 mmol of GaBr₃, and 4.0 mmol of InBr₃ were added and stirred at a temperature of 120° C. for 60 minutes [operation (1)]. The temperature was raised to 320° C., 5 mmol of S-oleylamine as a sulfur precursor and 1.1 mmol of lithiumhexamethyldisilazide (LiHMDS) were added and allowed to react for 10 minutes [operation (2)], and the temperature was lowered to room temperature to terminate the reaction, thereby preparing a quantum dot core.

### Example 2

A quantum dot core was prepared in the same manner as in Example 1, except that, in operation (2), 1.5 mmol of LiHMDS was added.

### Example 3

A quantum dot core was prepared in the same manner as in Example 1, except that, in operation (2), 1.7 mmol of LiHMDS was added.

### Example 4

A quantum dot core was prepared in the same manner as in Example 1, except that, in operation (2), a reaction time was set to 20 minutes.

### Example 5

A quantum dot core was prepared in the same manner as in Example 2, except that, in operation (2), a reaction time was set to 20 minutes.

### Example 6

A quantum dot core was prepared in the same manner as in Example 3, except that, in operation (2), a reaction time was set to 20 minutes.

### Example 7

A quantum dot core was prepared in the same manner as in Example 1, except that, in operation (2), a reaction temperature was raised by 3° C.

### Example 8

A quantum dot core was prepared in the same manner as in Example 1, except that, in operation (2), a reaction temperature was raised by 6° C.

### Example 9

A quantum dot core was prepared in the same manner as in Example 1, except that, in operation (2), a reaction temperature was raised by 9° C.

### Example 10

A quantum dot core was prepared in the same manner as in Example 1, except that, in operation (2), a reaction temperature was lowered by 3° C.

### Example 11

A quantum dot core was prepared in the same manner as in Example 1, except that, in operation (2), a reaction temperature was lowered by 6° C.

### Example 12

A quantum dot core was prepared in the same manner as in Example 1, except that, in operation (2), the reaction temperature was lowered by 9° C.

### Example 13

A quantum dot core was prepared in the same manner as in Example 4, except that, in operation (2), a reaction time was further extended by 10 minutes.

### Example 14

A quantum dot core was prepared in the same manner as in Example 1, except that, in operation (2), a reaction time was further extended by 15 minutes.

### Example 15

A quantum dot core was prepared in the same manner as in Example 1, except that, in operation (2), a reaction time was further extended by 20 minutes.

### Example 16

A quantum dot core was prepared in the same manner as in Example 1, except that, in operation (2), a reaction temperature was raised by 6° C. and a reaction time was further extended by 10 minutes.

### Example 17

A quantum dot core was prepared in the same manner as in Example 1, except that, in operation (2), a reaction temperature was raised by 6° C. and a reaction time was further extended by 15 minutes.

### Example 18

A quantum dot core was prepared in the same manner as in Example 1, except that, in operation (2), a reaction temperature was raised by 6° C. and a reaction time was further extended by 20 minutes.

### Comparative Example 1

A quantum dot core was prepared in the same manner as in Example 1, except that, in operation (2), a reaction was performed for 120 minutes without the addition of LiHMDS.

### Comparative Example 2

A quantum dot core was prepared in the same manner as in Example 1, except that, in operation (2), a reaction was performed for 10 minutes without the addition of LiHMDS.

### Comparative Example 3

A quantum dot core was prepared in the same manner as in Example 1, except that, in operation (2), a reaction was performed for 20 minutes without the addition of LiHMDS.

### Comparative Example 4

A quantum dot core was prepared in the same manner as in Example 1, except that, in operation (2), 2.9 mmol of LiHMDS was added.

A diameter of each of the quantum dot cores of the Examples and the Comparative examples was in a range of 5.0 nm to 6.0 nm.

### Preparation of Quantum Dot

### Example 19

In the latter part of Example 1, after the reaction was performed at a temperature of 200° C. for 5 minutes, the temperature was not lowered to terminate the reaction, and 0.5 mL of 2 M S-oleylamine and 0.5 mL of 2 M Zn carboxylate were added dropwise. A reaction was performed for 30 minutes, and the temperature was lowered to room temperature to terminate the reaction, thereby preparing a quantum dot with a core/shell structure.

### Example 20

A quantum dot with a core/shell structure was prepared in the same manner as in Example 19, except that the temperature was raised by 10° C.

### Example 21

A quantum dot with a core/shell structure was prepared in the same manner as in Example 19, except that the temperature was raised by 20° C.

### Example 22

A quantum dot with a core/shell structure was prepared in the same manner as in Example 19, except that a reaction time was further extended by 20 minutes.

### Example 23

A quantum dot with a core/shell structure was prepared in the same manner as in Example 19, except that a reaction time further extended by 40 minutes.

### Example 24

In the latter part of Example 3, after the reaction was performed at a temperature of 200° C. for 5 minutes, the temperature was not lowered to terminate the reaction, and 0.5 mL of 2 M S-oleylamine and 0.5 mL of 2 M Zn carboxylate were added dropwise. A reaction was performed for 30 minutes, and the temperature was lowered to room temperature to terminate the reaction.

### Comparative Example 5

In the latter part of Comparative Example 1, after the reaction was performed at a temperature of 200° C. for 5 minutes, the temperature was not lowered to terminate the reaction, and 0.5 mL of 2 M S-oleylamine and 0.5 mL of 2 M Zn carboxylate were added dropwise. A reaction was performed for 30 minutes, and the temperature was lowered to room temperature to terminate the reaction, thereby preparing a quantum dot with a core/shell structure.

Comparison of Quantum Dot Core Preparation Reaction Rates with UV Absorption Spectrum

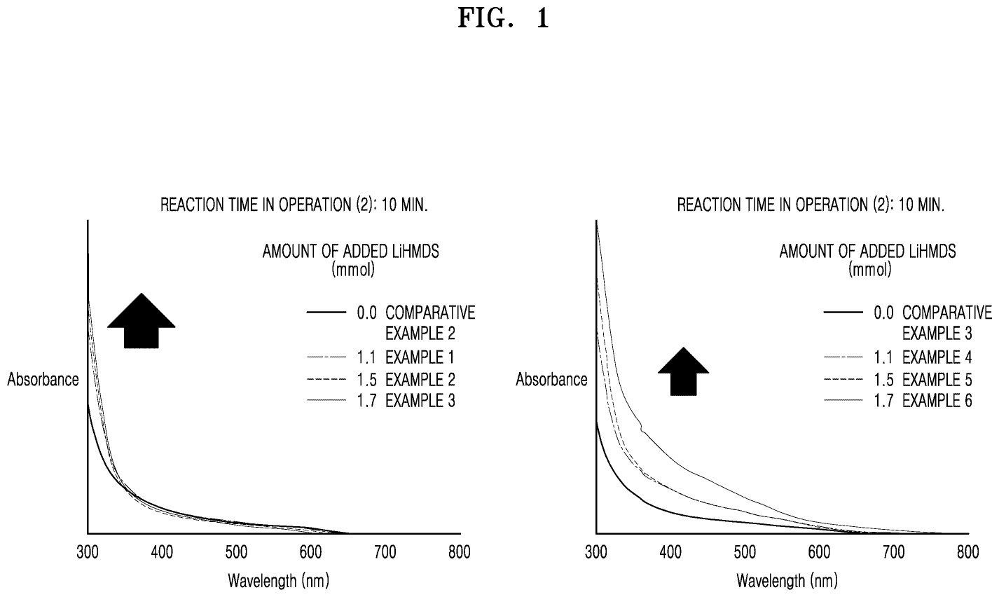

An ultraviolet (UV) absorption spectrum of the quantum dot core of each of Examples 1 to 6 and Comparative Example 2 and Comparative Example 3 was measured. Results thereof are shown in FIG. 1, respectively.

Referring to FIG. 1, it may be seen that the absorbance of Comparative Example 2 and Comparative Example 3 in which LiHMDS was not added was lower than the absorbance of Examples 1 to 6 in which LiHMDS was added. This means that in Examples 1 to 6, more quantum dot cores were generated as compared to Comparative Example 2 and Comparative Example 3. It may be seen that the absorbance increased as an amount of added LiHMDS increased, and the absorbance increased as a reaction time increased. Comparative Example 2 and Comparative Example 3 show that there is no change in absorbance even in case that a reaction time increases.

These results show that the added LiHMDS increased a reaction rate.

### Uniformity Evaluation

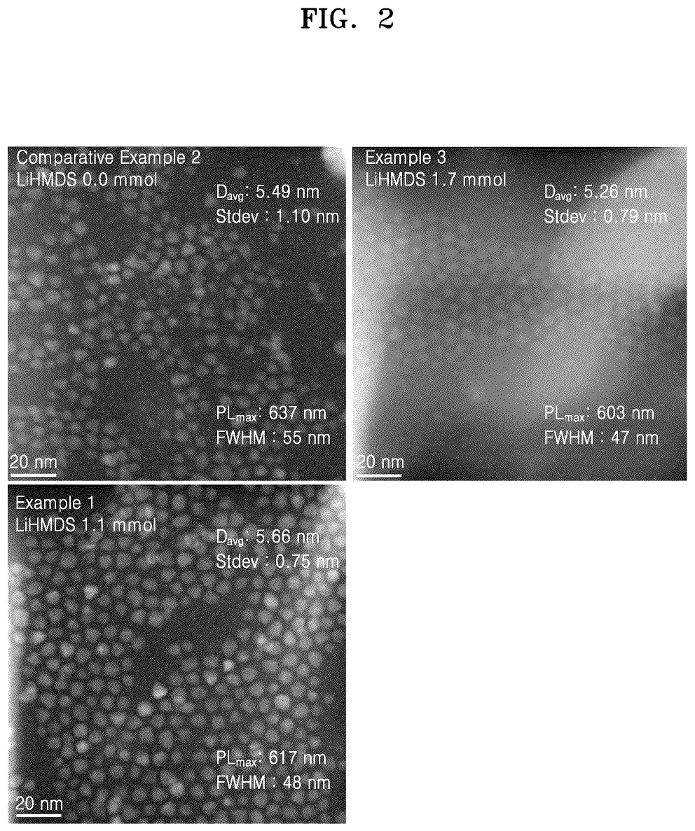

The quantum dot core of each of Examples 1, Example 3, and Comparative Example 2 was photographed by using an electron microscope. Results thereof are shown in FIG. 2 (magnification of 630,000), respectively.

Referring to FIG. 2, uniformity is calculated using the following equation:

$$uniformity = ( standard deviation / diameter ) \times 100$$

It may be seen that the uniformities of the quantum dot cores of Examples 1, Example 3, and Comparative Example 2 are 13%, 15%, and 20%, respectively.

It is considered that, by adding a non-nucleophilic base during a preparing process, a metal halide and a sulfur precursor became reactive, and a reaction rate was accelerated to generate many nuclei and rapidly consume monomers (Cu, Ga, In, and S) supplied for particle growth so that the quantum dot cores of Example 1 and Example 3 were relatively more uniform.

### Quantum Dot Core Full Width at Half Maximum Comparison

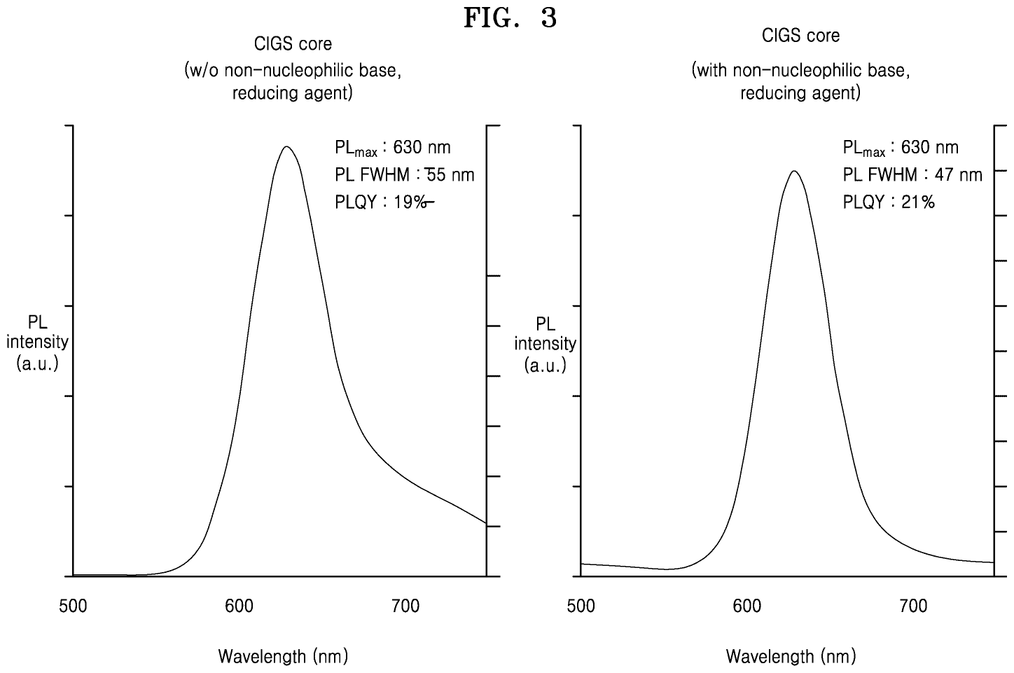

A full width at half maximum of the quantum dot core of each of Example 2 and Comparative Example 2 was measured. Results thereof are shown in FIG. 3.

Referring to FIG. 3, it may be seen that the full width at half maximum of the quantum dot core of Example is narrower than the full width at half maximum of the quantum dot core of Comparative Example.

This is well consistent with the result that the quantum dot core of Example is relatively more uniform.

### Quantum Dot Full Width at Half Maximum Comparison

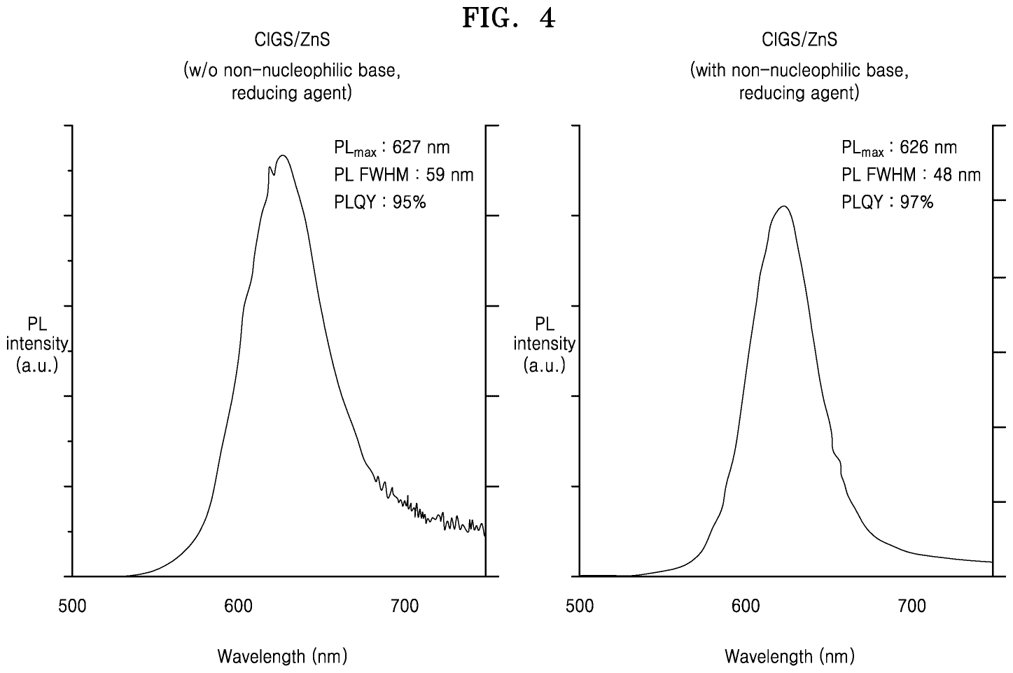

A full width at half maximum of the quantum dot of each of Comparative Example 5 and Example 22 was measured. Results thereof are shown in FIG. 4.

Referring to FIG. 4, it may be seen that the full width at half maximum of the quantum dot of the Examples is narrower than the full width at half maximum of the quantum dot of the Comparative Examples.

This is well consistent with the result that the quantum dot of the Examples are relatively more uniform.

### Comparison of Ratio Measurements of Organic and Inorganic Materials in Quantum Dot Core

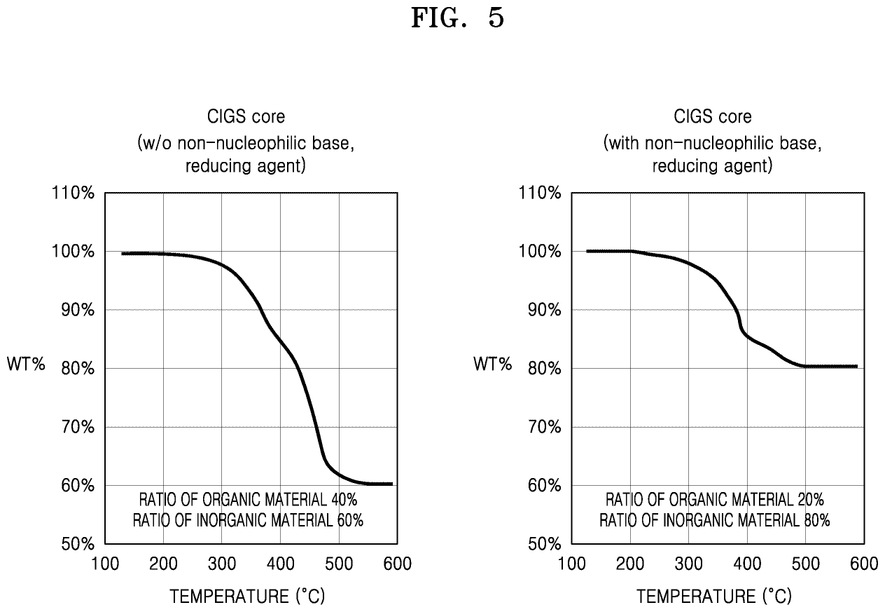

Ratios of organic and inorganic materials in the quantum dot core of each of Example 2 and Comparative Example 2 were measured by thermogravimetric analysis (TGA) (with SDT 650 manufactured by TA instruments). Results thereof are shown in FIG. 5.

Referring to FIG. 5, it may be seen that the ratio of the inorganic material of the quantum dot core of Example 2 is higher than the ratio of the inorganic material of the quantum dot core of Comparative Example 2.

This is because, by adding a non-nucleophilic base, a metal halide and a sulfur precursor became reactive to accelerate a reaction rate and significantly reduce an amount of an organic material (for example, a polymer film) present on a core surface.

### Comparison of Ratio Measurements of Organic and Inorganic Materials in Quantum Dot

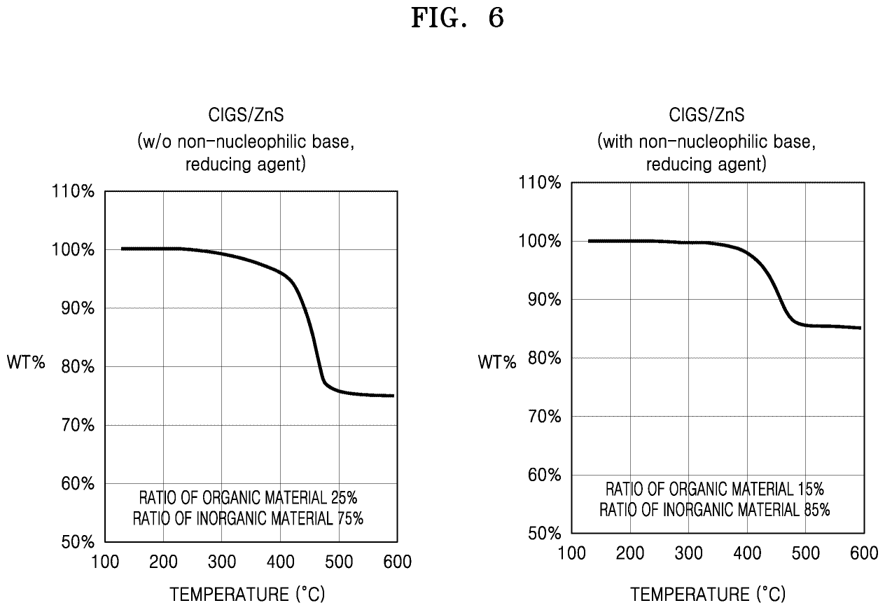

Ratios of organic and inorganic materials in the quantum dot of each of Example 22 and Comparative Example 5 were measured by TGA. Results thereof are shown in FIG. 6.

Referring to FIG. 6, it may be seen that the ratio of the inorganic material of the quantum dot of Example 22 is higher than the ratio of the inorganic material of the quantum dot of Comparative Example 5.

This is well consistent with the result that the ratio of the inorganic material of the quantum dot core of Example 2 is higher than the ratio of the inorganic material of the quantum dot core of Comparative Example 2.

### Photostability Comparison

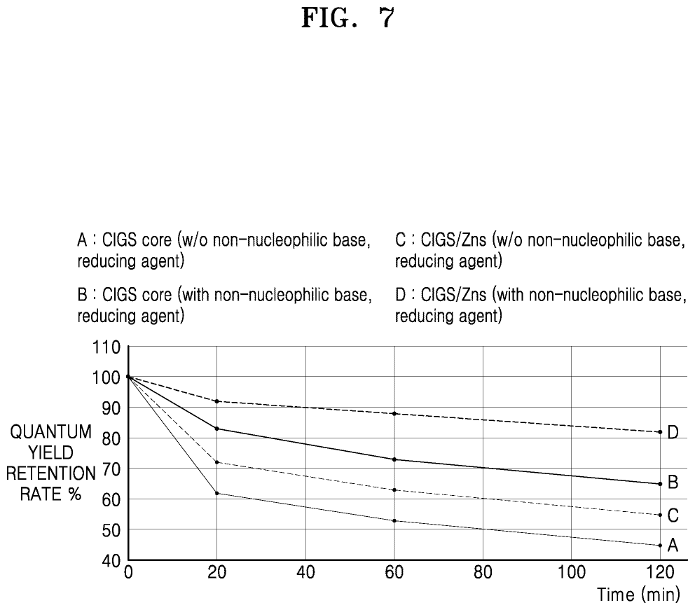

QY retention rates of the quantum dot core of each of Example 1 and Comparative Example 1 and the quantum dot of each of Example 19 and Comparative Example 5 were measured to compare photostabilities by using the following equation. Results thereof are shown in FIG. 7.

blue light exposure stability value=(PLQY before exposure)/(PLQY after exposure)×100

A solution with a concentration at which an optical density was 1 at 450 nm was prepared. The solution was exposed to a light exposure environment of 200 nit at 450 nm for 2 hours and left to measure a PLQY value. The PLQY value was measured before exposure.

Referring to FIG. 7, it can be seen that the photostability of the quantum dot core of Example 1 is 65% or more, and the photostability of the quantum dot of Example 19 is 80% or more, each of which is higher than the photostabilities of Comparative Examples.

A maximum emission wavelength, a full width at half maximum, a ratio of an inorganic material, a ratio of an organic material, a component ratio, and the like of each of the quantum dot cores and the quantum dots of some Examples and Comparative Examples are shown in Table 1. The ratio of the inorganic material and the ratio of the organic material were measured by TGA, and the component ratio was measured by inductively-couple plasma (ICP) analysis (with Agilent 7850 ICP-MS) and calculated.

TABLE 1

| | | PL | Inorganic | Molar | Molar | Molar | Molar |
|---|---|---|---|---|---|---|---|
| | PLₘₐₓ | FWHM | material | ratio | ratio | ratio | ratio |
| | (nm) | (nm) | wt % | of Cu | of In | of Gs | of S |
| Comparative | 630 | 55 | 60 | 0.129 | 0.354 | 0.091 | 0.426 |
| Example 2 | | | | | | | |
| Example 1 | 617 | 48 | 82 | 0.146 | 0.284 | 0.097 | 0.473 |
| Example 2 | 610 | 47 | 80 | 0.124 | 0.356 | 0.079 | 0.441 |
| Example 3 | 603 | 47 | 82 | 0.114 | 0.381 | 0.072 | 0.433 |
| Comparative | — | — | Fail | | | | |
| Example 4 | | | | | | | |
| Example 7 | 635 | 46 | 81 | 0.104 | 0.387 | 0.102 | 0.407 |
| Example 8 | 637 | 44 | 82 | 0.082 | 0.431 | 0.100 | 0.387 |
| Example 9 | 634 | 44 | 81 | 0.106 | 0.387 | 0.076 | 0.431 |
| Example 10 | 636 | 47 | 83 | 0.100 | 0.415 | 0.067 | 0.419 |
| Example 11 | 629 | 47 | 82 | 0.136 | 0.290 | 0.100 | 0.474 |
| Example 12 | 639 | 46 | 82 | 0.155 | 0.234 | 0.116 | 0.496 |
| Example 13 | 627 | 44 | 81 | 0.064 | 0.389 | 0.154 | 0.394 |
| Example 14 | 630 | 43 | 82 | 0.061 | 0.370 | 0.170 | 0.399 |
| Example 15 | 632 | 44 | 83 | 0.060 | 0.380 | 0.159 | 0.400 |
| Example 16 | 635 | 42 | 82 | 0.057 | 0.369 | 0.176 | 0.398 |
| Example 17 | 640 | 42 | 83 | 0.064 | 0.358 | 0.195 | 0.382 |
| Example 18 | 633 | 41 | 84 | 0.094 | 0.317 | 0.163 | 0.427 |
| Comparative | 627 | 59 | 75 | 0.406 | 0.303 | 0.291 | — |
| Example 5 | | | | | | | |
| Example 19 | 615 | 50 | 85 | 0.402 | 0.337 | 0.261 | — |
| Example 24 | 601 | 49 | 85 | 0.398 | 0.353 | 0.249 | — |
| Example 20 | 615 | 49 | 86 | 0.341 | 0.287 | 0.372 | — |
| Example 21 | 614 | 51 | 86 | 0.364 | 0.265 | 0.371 | — |
| Example 22 | 626 | 48 | 85 | 0.423 | 0.376 | 0.201 | — |
| Example 23 | 615 | 49 | 85 | 0.442 | 0.430 | 0.128 | — |

$$inorganic material wt \% = ( inorganic material wt / ( organic material + inorganic material wt ) ) \times 100$$

in Comparative Example 2 and Examples 1 to 18,

$$\begin{matrix}molar ratio of Cu = Cu mole / ( Cu mole + In mole + Ga mole + S mole ) \\ molar ratio of In = In mole / ( Cu mole + In mole + Ga mole + S mole ) \\ molar ratio of Ga = Ga mole / ( Cu mole + In mole + Ga mole + S mole ) \\ molar ratio of S = S mole / ( Cu mole + In mole + Ga mole + S mole )\end{matrix}$$

in Comparative Example 5 and Examples 20 to 24,

$$molar ratio of Cu = Cu mole / + In mole + Ga mole )$$

In Comparative Example 5 and Examples 19 to 24, shell thicknesses were all in a range of about 0.7 nm to about 1.0 nm.

In case that the temperature and reaction time deviated from the above ranges in a process of preparing a quantum dot core, core synthesis failed, and a case in which a molar ratio of Cu, a molar ratio of In, a molar ratio of Ga, and a molar ratio of S deviated from the ranges in Table 1 was not confirmed.

Referring to FIGS. 8 and 9, the quantum dot may be applied to an emission layer to manufacture a light-emitting device, and since the light-emitting device may be manufactured using a general method, specific details are omitted.

In a quantum dot core according to an embodiment, a ratio of an inorganic material may be greater than or equal to about 80 wt %, and a full width at half maximum of the quantum dot core including the inorganic material may be less than or equal to about 49 nm.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A quantum dot core comprising:
a Group I-III-VI semiconductor compound,
wherein a ratio of an inorganic material in the quantum dot core is greater than or equal to about 80 wt %.

2. The quantum dot core of claim 1, wherein
the quantum dot core comprises a plurality of quantum dot cores,
a uniformity of the plurality of quantum dot cores is less than or equal to about 19%, and
$$uniformity = ( standard deviation of the plurality of quantum dot cores / average diameter of the plurality of quantum dots ) \times 100.$$

3. The quantum dot core of claim 1, wherein the quantum dot core has a diameter in a range of about 1.0 nm to about 10 nm.

4. The quantum dot core of claim 1, wherein a full width at half maximum of the quantum dot core is less than or equal to about 49 nm.

5. The quantum dot core of claim 1, wherein the Group I-III-VI semiconductor compound comprises AgInS, AgInS₂, CuInS, CuInS₂, CuGaO₂, AgGaO₂, AgAlO₂, CuInGaS, CuInGaS₂, AgInGaS, AgInGaS₂, or a combination thereof.

6. The quantum dot core of claim 1, wherein
the Group I-III-VI semiconductor compound comprises CuInGaS, CuInGaS₂, or a combination thereof, and
a molar ratio of Cu to a total number of moles of Cu, In, Ga, and S in the quantum dot core is in a range of about 0.01 to about 0.30.

7. The quantum dot core of claim 1, wherein
the Group I-III-VI semiconductor compound comprises CuInGaS, CuInGaS₂, or a combination thereof, and
a molar ratio of In to a total mole number of Cu, In, Ga, and S in the quantum dot core is in a range of about 0.10 to about 0.60.

8. The quantum dot core of claim 1, wherein
the Group I-III-VI semiconductor compound comprises CuInGaS, CuInGaS₂, or a combination thereof, and
a molar ratio of Ga to a total number of moles of Cu, In, Ga, and S in the quantum dot core is in a range of about 0.01 to about 0.30.

9. The quantum dot core of claim 1, wherein
the Group I-III-VI semiconductor compound comprises CuInGaS, CuInGaS₂, or a combination thereof, and
a molar ratio of S to a total number of moles of Cu, In, Ga, and S in the quantum dot core is in a range of about 0.30 to about 0.70.

10. The quantum dot core of claim 1, wherein
the quantum dot core has a blue light exposure stability value greater than or equal to about 65%,
the blue light exposure stability is obtained by exposing a solution, which has a concentration at which an optical density is 1 at 450 nm, to a light exposure environment of 200 nit at 450 nm for 2 hours and leaving the solution to obtain a photoluminescence quantum yield (PLQY) value, and
$$blue light exposure stability value = ( PLQY before exposure ) / ( PLQY after exposure ) \times 100.$$

11. A quantum dot comprising:
the quantum dot core of claim 1, and a shell,
wherein the shell comprises ZnSe, ZnS, ZnTe, ZnO, ZnMg, ZnMgSe, ZnMgS, ZnMgAl, GaSe, GaTe, GaP, GaAs, GaSb, InAs, InSb, AlP, AlAs, AlSb, MnS, MnSe, MgS, MgSe, CdS, CdSe, CdTe, ZnSeS, ZnTeS, HgS, HgSe, HgTe, InP, InGaP, or a combination thereof.

12. The quantum dot of claim 11, wherein a ratio of an inorganic material in the quantum dot is greater than or equal to about 80 wt %.

13. The quantum dot of claim 11, wherein
the shell comprises ZnS, and
a molar ratio of Cu to a total number of moles of the quantum dot is in a range of about 0.20 to about 0.60.

14. The quantum dot of claim 11, wherein
the shell comprises ZnS, and
a molar ratio of In to a total number of moles of the quantum dot is in a range of about 0.10 to about 0.60.

15. The quantum dot of claim 11, wherein
the shell comprises ZnS, and
a molar ratio of Ga to a total number of moles of the quantum dot is in a range of about 0.05 to about 0.50.

16. An electronic apparatus comprising:
a light-emitting device comprising a first electrode, a second electrode facing the first electrode, and an interlayer arranged between the first electrode and the second electrode and comprising an emission layer;
a thin film transistor; and
the quantum dot of claim 11, wherein
the thin film transistor comprises a source electrode and a drain electrode, and
the first electrode of the light-emitting device is electrically connected to at least one of the source electrode and the drain electrode of the thin film transistor.

17. The electronic apparatus of claim 16, further comprising:
a color conversion layer,
wherein the color conversion layer comprises the quantum dot.

18. The electronic apparatus of claim 16, further comprising a capping layer.

19. The electronic apparatus of claim 18, wherein the capping layer comprises a material having a refractive index (at 589 nm) greater than or equal to about 1.6.

20. The electronic apparatus of claim 16, wherein the electronic apparatus comprises an authentication apparatus, a display, a light sources, a lighting, a personal computer, a mobile phone, a digital camera, an electronic organizer, an electronic dictionary, an electronic game machine, medical instrument, a fish finder, a measuring instrument, a meters, or a projector.
